(19) United States
(12) Patent Application Publication
(10) Pub. No.: US 2026/0366618 A1
(43) Pub. Date: Nov. 19, 2026

(54) MODIFIED CARBON-BASED COATING LAYER FOR PISTON RING APPLICATIONS

(71) Applicant: Federal-Mogul Burscheid GmbH, Burscheid (DE)

(72) Inventors: Gregor ENGLBERGER, Burscheid (DE); Peter-Klaus ESSER, Burscheid (DE); Rainer CAPELLMANN, Burscheid (DE); Blair JENNESS, Burscheid (DE)

(21) Appl. No.: 19/207,570

(22) Filed: May 14, 2025

(51) Int. Cl. F16J 9/26; C23C 14/06

(52) U.S. Cl. CPC F16J 9/26; C23C 14/0605

(57) ABSTRACT

A piston ring including a multi-layer coating which can be manufactured by an arc-based physical vapor deposition (PVD) process is provided. The coating includes a top layer and a functional layer which are both formed of a carbon-based material, typically hydrogen-free diamond-like carbon (DLC). The top layer has a Young's modulus of 50 to less than 180 GPa and a thickness of 0.1 to 40 μm. The functional layer has a Young's modulus greater than the Young's modulus of the top layer. The functional layer also has a thickness greater than the thickness of the top layer. The Young's modulus of the functional layer is typically 180 to 700 GPa, and the thickness of the functional layer is typically 1 to 80 μm. The coating provides beneficial tribological properties, such as a low friction coefficient, high wear resistance, good scuffing resistance, and acceptable roughness, without a complex smoothing process.

### BACKGROUND OF THE INVENTION

### 1. Field of the Invention

This invention relates generally to a coating for providing wear resistance to a piston ring. The invention also relates to a piston ring including a wear resistant coating, and a method of manufacturing the same.

### 2. Related Art

Carbon-based coatings, such as hydrogen-free diamond-like carbon (DLC) coatings, can be applied to piston rings to provide beneficial tribological properties, such as a low friction coefficient, high wear resistance, and good scuffing resistance. A physical vapor deposition (PVD) process can be used to apply these coatings to a metal substrate, such as a piston ring substrate. The PVD process typically includes applying an electric arc to a cathode target material, for example a carbon-based material. The arc vaporizes the target material which then condenses on the metal substrate and forms one or more layers.

However, a possible disadvantage of the arc-based PVD process, for example when the process is unfiltered and used to apply the carbon-based material to the substrate, is a large amount of macro particles released from the target material which become embedded in the layers on the substrate. The embedded macro particles can cause increased roughness, which leads to wear on a counterpart component. In this case, a complex smoothing process is typically required to reduce the roughness of the coating and avoid the excess wear. Accordingly, improvements to the coated piston ring and process used to form the coated piston ring are desired.

### SUMMARY

One aspect of the disclosure provides a coating for a piston ring. The coating includes a top layer which is carbon-based. The top layer has a Young's modulus of 50 to less than 180 GPa and a thickness of 0.1 to 40 μm. The coating also includes a functional layer below the top layer. The functional layer is carbon-based and has a Young's modulus greater than the Young's modulus of the top layer. The functional layer also has a thickness greater than the thickness of the top layer.

Another aspect of the disclosure provides a piston ring including a substrate formed of metal and a coating applied to the substrate. The coating includes a functional layer which is carbon-based. The coating also includes a top layer which is carbon-based disposed on the functional layer. The top layer has a Young's modulus of 50 to less than 180 GPa and a thickness of 0.1 to 40 μm. The top layer has a Young's modulus less than a Young's modulus of the functional layer, and the top layer has a thickness less than a thickness of the functional layer.

Another aspect of the disclosure provides a method of manufacturing a coating for a piston ring. The method includes applying a functional layer over a substrate by a physical vapor deposition (PVD) process; and applying a top layer to the functional layer by the physical vapor deposition (PVD) process. The top layer is carbon-based and has a Young's modulus which is less than a Young's modulus of the functional layer. The Young's modulus of the top layer ranges from 50 to less than 180 GPa. The top layer also has a thickness which is less than a thickness of the functional layer and ranges from 0.1 to 40 μm.

The reduced Young's modulus of the top layer relative to the functional layer makes it easier to smooth the coating, compared to the coatings described above which are formed by the arc-based PVD process. Also, due to the reduced Young's modulus of the coating, surface roughness of the top layer no longer causes excess wear on a counterpart component during operation. Thus, the complex smoothing process typically required after the PVD process can be drastically reduced or eliminated.

In addition, the top layer is able to accelerate running-in behavior of the coating to achieve stable oil consumption and blow-by values more quickly. Initial wear of the coating during the running-in period can also be reduced.

### BRIEF DESCRIPTION OF THE DRAWINGS

Other advantages of the present invention will be readily appreciated, as the same becomes better understood by reference to the following detailed description when considered in connection with the accompanying drawings wherein:

FIG. 1 is a cross-sectional view of a piston ring including a coating according to an example embodiment; and

FIG. 2 is a cross-sectional view of the coating shown under a microscope according to an example embodiment.

### DETAILED DESCRIPTION OF EXAMPLE EMBODIMENTS

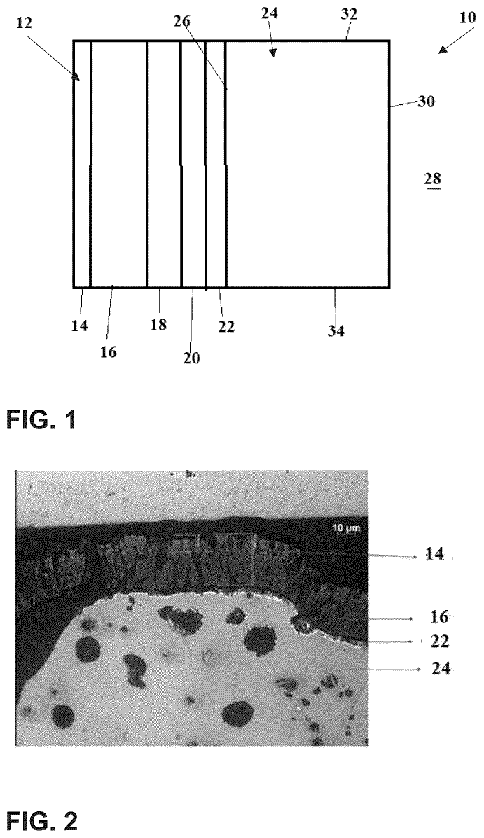

One aspect of the disclosure provides a piston ring 10 including a multi-layer coating 12 which can be manufactured by an efficient physical vapor deposition (PVD) process. The coating 12 also provides beneficial tribological properties, such as a low friction coefficient, high wear resistance, good scuffing resistance, and acceptable roughness. FIGS. 1 and 2 show cross-sections of the coating 12 according to example embodiments.

The coating 12 includes a top layer 14 which is carbon-based disposed on a functional layer 16. The top layer 14 is preferably formed of diamond-like carbon (DLC) and free of hydrogen. The top layer 14 may include at least one of nitrogen and argon, preferably nitrogen. The nitrogen is typically present in an amount of less than 30 atomic percent (at. %), based on the total atomic weight of the top layer 14. The top layer 14 can have a gradient structure, in which case the amount of nitrogen in the top layer 14 increases in a direction moving away from the functional layer 16.

Accordingly to example embodiments, the top layer 14 includes the nitrogen in an amount of 5 to 25 atomic percent (at. %), oxygen in an amount of less than 5 atomic percent (at. %), other elements besides nitrogen, carbon, and oxygen in a total amount of less than 2 atomic percent (at. %), and a remainder of carbon, based on the total atomic weight of the top layer 14. Typically, the top layer 14 includes a ratio of sp³ to sp² hybridized carbon atoms of less than 0.6.

The top layer 14 preferably has a reduced Young's modulus compared to the functional layer 16. The Young's modulus of the top layer 14 is typically 50 to less than 180 GPa, or 90 to 150 GPa. In an as-formed condition, prior to any smoothing process, when the top layer 14 is formed to a thickness of 20 μm, the top layer 14 typically has a roughness (Rz) of greater than 2 μm to about 7 μm, for example about 4.5 μm; a roughness (Rk) of greater than 0.6 μm to about 3.0 μm, for example about 1.8 μm; and a roughness (Rpk) of greater than 0.2 μm to about 3.2 μm, for example 1.8 μm; and a roughness (Rvk) of greater than 0.05 um to about 1.5 um, for example about 0.5 μm. The roughness is determined by a tactile measurement, which includes physically tracing the surface of the top layer 14 using a stylus and measuring the profile of the surface. The top layer 14 also typically has a thickness ranging from 0.1 to 40 μm, or 0.5 to 10 μm.

The reduced Young's modulus of the top layer 14 allows for easier smoothing of the top layer 14 after the PVD process. Also, due to the reduced Young's modulus of the top layer 14, the surface roughness of the top layer 14 no longer causes excessive wear on a counterpart component during operation of the piston ring 10. Thus, the complex smoothing process required for the comparative carbon-based coatings is no longer required.

The functional layer 16 is disposed below the top layer 14 and is applied prior to the top layer 13 during the PVD process. The functional layer 16 is preferably formed of diamond-like carbon (DLC) and free of hydrogen. The functional layer 16 is typically amorphous in structure. Accordingly to example embodiments, the functional layer 16 includes oxygen in an amount of less than 5 atomic percent (at. %), other elements besides carbon, oxygen in a total amount of less than 2 atomic percent (at. %), and a remainder of carbon, based on the total atomic percent (at. %) of the functional layer 16. Typically, the functional includes 16 a ratio of sp³ to sp² hybridized carbon atoms of greater than 0.65.

The functional layer 16 has a Young's modulus which is greater than the Young's modulus of the top layer 14. According to example embodiments, the Young's modulus of the functional layer 16 is 180 to 700 GPa, 180 to 500 GPa, 180 to 450 GPa, or 180 to 350 GPa. The functional layer 16 also has a thickness greater than the thickness of the top layer 14. Typically, the thickness of the functional layer 16 ranges from 1 to 80 μm, 1 to 50 μm, or 3 to 50 μm.

According to example embodiments, the coating 12 further includes a crystalline layer 18 which is carbon-based and located below the functional layer 16. The crystalline layer 18 typically has a thickness ranging from 5 to 200 nm, and preferably 10 to 50 nm.

The coating 12 of the example embodiments also includes a CrC layer 20 containing chromium and carbon located below the crystalline layer. The CrC layer 20 typically has a thickness ranging from 1 to 20 nm, and preferably 3 to 10 nm.

The coatings 12 of the example embodiments shown in FIGS. 1 and 2 further include an interlayer 22 containing a carbide-forming material located below the CrC layer 20. The carbide-forming material is typically at least one of chromium, titanium, and tungsten, but typically chromium. The chromium is typically present in an amount of greater than 98 atomic percent (at. %) and other elements may be present in an amount no great than 2 atomic percent (at. %), based on the atomic weight of the material. The interlay 22 typically has a thickness ranging from 0.5 to 2 μm, and preferably 0.1 to 1 μm. The interlayer 22 is typically formed by the PVD process.

The coating 12 can be applied to various different substrates, but according to the example embodiments, the coating is applied to a substrate 24 formed of metal for use as the piston ring 10. The metal of the substrate 24 is typically steel or another iron-based material.

As shown in FIGS. 1 and 2, the substrate 24 includes a running surface 26 extending circumferentially around a center opening 28, an inside surface 30 facing away from the running surface 26 and toward the center opening 28, an upper side surface 32 extending from the running surface 26 to the inside surface 30, and a lower side surface 34 facing away from the upper side surface 32 and extending from the running surface 26 to the inside surface 30.

The coating 12 is disposed on at least one of the running surface 26, the inside surface 30, the upper side surface 32, and the lower side surface 34. Typically, the coating 12 is disposed on the running surface 26. For example, the coating 12 could be disposed on the running surface 26 only, the running surface 26 and one or both of the upper and lower side surfaces 32, 34, only one of the side surfaces 32 or 34, only both of the side surfaces 32, 34, or all of the surfaces 26, 30, 32, and 34.

Another aspect of the disclosure provides a method of manufacturing the coating 12 for the piston ring 10 by a physical vapor deposition (PVD) process, for example an arc-based PVD process. The PVD process begins by placing the substrate 24 in a vacuum chamber. The process further applying the functional layer 14 and the top layer 12 to the substrate 24 in the vacuum chamber.

The arc-based PVD process generally includes placing any material used to form the coating 12 in the vacuum chamber. The process then typically includes introducing a process gas containing nitrogen or argon into the vacuum chamber while the vacuum chamber is at a pressure ranging from 1.0⁻⁴−1.0⁻² mbar. According to the example embodiments, a high-current, low-voltage electric arc is applied to the chamber. The material used to form the coating 12 acts as a cathode target material. The electric arc strikes the material, and the electric arc vaporizes the material. The vaporized material is contained in the vacuum chamber and condenses on the substrate 24. Due to the relatively higher pressure during the PVD process, the top layer 14 may have a lower amount of macro particles embedded therein, relative to comparative carbon-base coatings.

In the example embodiments, when the coating 12 includes the interlayer 22, the method includes placing a carbide-forming material used to form the interlayer 22 in the vacuum chamber. The method then includes applying the electric arc to the carbide-forming material while the vacuum chamber is under pressure so that the carbide-forming material vaporizes and condenses on one or more surfaces 26, 30, 32, and 34 of the metal substrate 24 and forms the interlayer 22. As stated above, the carbide-forming material is typically at least one of chromium, titanium, and tungsten, but typically chromium. The interlay 22 is typically formed to have a thickness ranging from 0.5 to 2 μm, and preferably 0.1 to 1 μm.

In the example embodiments, when the coating 12 includes the CrC layer 20, the method includes placing a material containing chromium and carbon in the vacuum chamber. The method then includes applying the electric arc to the material while the vacuum chamber is under pressure so that the material vaporizes and condenses on the interlayer 22 to form the CrC layer 20. The CrC layer 20 is typically formed to a thickness ranging from 1 to 20 nm, and preferably 3 to 10 nm.

In the example embodiments, when the coating 12 includes the crystalline layer 18, the method includes placing a carbon-based material in the vacuum chamber. The method then includes applying the electric arc to the material while the vacuum chamber is under pressure so that the material vaporizes and condenses on the interlayer 22 to form the crystalline layer 18. The CrC layer 20 is typically formed to a thickness ranging from 5 to 200 nm, and preferably 10 to 50 nm.

The PVD process according to the example embodiments next includes forming the functional layer 16. This step includes applying the electric arc to the material used to form the functional layer, typically the hydrogen-fee diamond-like carbon (DLC) which free of hydrogen, while the vacuum chamber is under pressure so that the material vaporizes and condenses on the CrC layer 20 to form the functional layer 16. A process gas, such as nitrogen or argon, which is used to form the other layers 14, 18, 20, is not required to form the functional layer 16. The functional layer 16 is typically formed to a thickness ranging from 1 to 80 μm, 1 to 50 μm, or 3 to 50 μm.

The PVD process according to the example embodiments next includes forming the top layer 14. This step includes applying the electric arc to the material used to form the functional layer, typically the hydrogen-fee diamond-like carbon (DLC), while the vacuum chamber is under pressure so that the material vaporizes and condenses on the functional layer 16 to form the top layer 14. This step may include forming a gradient structure, in which case the process can include increasing the amount of nitrogen or argon provided during the step of applying the electric arc and forming the top layer 14. The top layer 14 is typically formed to a thickness ranging from 1 to 80 μm, 1 to 50 μm, or 3 to 50 μm.

In the as-formed condition, immediately after the PVD process and prior to any smoothing or other finishing steps, the top layer 14 has a roughness (Rz) of greater than 2 μm, a roughness (Rk) of greater than 0.6 μm, and a roughness (Rpk) of greater than 0.2 μm. The roughness is determined by a tactile measurement, which includes physically tracing the surface of the top layer 14 using a stylus and measuring the profile of the surface.

The process can optionally include smoothing or another finishing step on the top layer 14 after the PVD process, if needed. The reduced Young's modulus of the top layer makes the top layer 14 easier to smooth. Also, due to the Young's modulus of the top layer 14, the surface roughness of the top layer 14 does not cause excessive wear on a counterpart component during operation. In summary, due to the composition, properties, especially the Young's modulus, and process used to form the top layer 14, the complex smoothing process is not required.

As stated above, the coated piston ring 10 described above provides significant improvements over comparative coated piston rings. The reduction in the Young's modulus occurs to an extent that cannot be achieved by simply reducing the bias voltage or by coating without bias voltage due to the inherent energy of the carbon ions. In order to achieve the low Young's modulus, additional process gas is introduced into the vacuum chamber to reduce the inherent energy of the carbon atoms. The free path of the carbon atoms is reduced by admitting the process gas, which significantly reduces the kinetic energy of the carbon particles. This significantly increases the proportion of sp² bonds in the growing coating 12 and reduces the Young's modulus.

As indicated above, a potential benefit of the softer top layer 14 is that the complex smoothing process can be eliminated, which saves time and costs. In other words, the amount of smoothing required to avoid excess wear can be reduced or the smoothing process can be eliminated altogether. The smooth top layer 14 is able to accelerate the running-in behavior of the coating 12 to achieve stable oil consumption and blow-by values more quickly. Initial wear of the coating 12 during the running-in period can also be reduced.

Obviously, many modifications and variations of the present invention are possible in light of the above teachings and may be practiced otherwise than as specifically described while within the scope of the following claims.

1. A coating for a piston ring, comprising:
a top layer being carbon-based, the top layer having a Young's modulus of 50 to less than 180 GPa and a thickness of 0.1 to 40 μm, the top layer having a ratio of sp³ to sp² hybridized carbon atoms of less than 0.6; and
a functional layer below the top layer, the functional layer being carbon-based, the functional layer having a Young's modulus greater than the Young's modulus of the top layer, the functional layer having a thickness greater than the thickness of the top layer, and the functional having a ratio of sp³ to sp² hybridized carbon atoms of greater than 0.65.

2. The coating of claim 1, wherein the Young's modulus of the top layer is to 90 to 150 GPa and the thickness of the top layer is 0.5 to 10 μm.

3. The coating of claim 1, wherein the top layer is formed of diamond-like carbon (DLC) and is free of hydrogen.

4. The coating of claim 1, wherein the top layer contains nitrogen or argon.

5. The coating of claim 4, wherein the top layer includes the nitrogen, and the amount of nitrogen in the top layer increases in a direction moving away from the functional layer.

6. The coating of claim 4, wherein the top layer includes the nitrogen in an amount of less than 30 atomic percent; oxygen in an amount of less than 5 atomic percent; other elements besides nitrogen, carbon, and oxygen in a total amount of less than 2 atomic percent; and a remainder of carbon, based on the total atomic weight of the top layer.

7. The coating of claim 6, wherein the top layer includes the nitrogen in an amount of 5 to 25 atomic percent, based on the total atomic weight of the top layer.

8. (canceled)

9. The coating of claim 1, wherein the top layer, in an as-formed condition prior to any smoothing process, has a roughness (Rz) of greater than 2 μm, a roughness (Rk) of greater than 0.6 μm, and a roughness (Rpk) of greater than 0.2 μm.

10. The coating of claim 1, wherein the top layer includes embedded macro particles.

11. The coating of claim 1, wherein the functional layer is formed of diamond-like carbon (DLC), is free of hydrogen, and is amorphous.

12. The coating of claim 1, wherein the functional layer includes oxygen in an amount of less than 5 atomic percent; other elements besides carbon and oxygen in a total amount of less than 2 atomic percent, and a remainder of carbon, based on the total atomic weight of the functional layer.

13. The coating of claim 1, wherein the Young's modulus of the functional layer is 180 to 700 GPa, and the thickness of the functional layer is 1 to 80 μm.

14. The coating of claim 13, wherein the Young's modulus of the functional layer is 180 to 450 GPa, and the thickness of the functional layer is 3 to 50 μm.

15. (canceled)

16. The coating of claim 1, wherein the coating further includes a crystalline layer which is carbon-based below the functional layer, a CrC layer containing chromium and carbon below the crystalline layer, and an interlayer containing a carbide-forming material below the CrC layer.

17. The coating of claim 1, wherein the Young's modulus of the top layer is to 90 to 150 GPa and the thickness of the top layer is 0.5 to 10 μm;
the top layer is formed of diamond-like carbon (DLC) and is free of hydrogen;
the top layer includes nitrogen, and the amount of nitrogen in the top layer increases in a direction moving away from the functional layer;
the top layer includes the nitrogen in an amount of 5 to 25 atomic percent, oxygen in an amount of less than 5 atomic percent, other elements besides nitrogen, carbon, and oxygen in a total amount of less than 2 atomic percent, and a remainder of carbon, based on the total atomic weight of the top layer;
the top layer, in an as-formed condition prior to any smoothing process, has a roughness (Rz) of greater than 2 μm, a roughness (Rk) of greater than 0.6 μm, and a roughness (Rpk) of greater than 0.2 μm;
the functional layer is formed of diamond-like carbon (DLC) and is free of hydrogen;
the functional layer is amorphous;
the functional layer includes oxygen in an amount of less than 5 atomic percent, other elements besides carbon, oxygen in a total amount of less than 2 atomic percent, and a remainder of carbon, based on the total atomic weight of the top layer;
the Young's modulus of the functional layer is 180 to 450 GPa;
the thickness of the functional layer is 3 to 50 μm;
the coating further including a crystalline layer which is carbon-based below the functional layer;
a CrC layer containing chromium and carbon below the crystalline layer; and
an interlayer containing a carbide-forming material below the CrC layer, wherein the carbide-forming material is chromium.

18. A piston ring, comprising:
a substrate formed of metal; and
a coating applied to the substrate, wherein the coating includes:
a functional layer, the functional layer being carbon-based, the functional having a ratio of sp³ to sp² hybridized carbon atoms of greater than 0.65; and
a top layer disposed on the functional layer, the top layer being carbon-based, the top layer having a Young's modulus of 50 to less than 180 GPa and a thickness of 0.1 to 40 μm, the top layer having a Young's modulus less than a Young's modulus of the functional layer, the top layer having a thickness less than a thickness of the functional layer, and the top layer having a ratio of sp³ to sp² hybridized carbon atoms of less than 0.6.

19. The piston ring of claim 18, wherein the substrate includes a running surface extending circumferentially around a center opening, an inside surface facing away from the running surface and toward the center opening, an upper side surface extending from the running surface to the inside surface, and a lower side surface facing away from the upper side surface and extending from the running surface to the inside surface.

20. The piston ring of claim 19, wherein the coating is disposed on the running surface.

21. The piston ring of claim 19, wherein the coating is disposed on at least one of the running surface, the upper side surface, and the lower side surface.

22. A method of manufacturing a coating for a piston ring, comprising the steps of:
applying a functional layer over a substrate by a physical vapor deposition (PVD) process, the functional having a ratio of sp³ to sp² hybridized carbon atoms of greater than 0.65; and
applying a top layer to the functional layer by the physical vapor deposition (PVD) process;
wherein the top layer is carbon-based, the top layer has a Young's modulus which is less than a Young's modulus of the functional layer and ranges from 50 to less than 180 GPa, the top layer has a thickness which is less than a thickness of the functional layer and ranges from 0.1 to 40 μm, and the top layer has a ratio of sp³ to sp² hybridized carbon atoms of less than 0.6.

23. The method of claim 22, wherein the step of applying the top layer includes introducing a process gas containing nitrogen or argon into a vacuum chamber during the PVD process.

24. The method of claim 23, wherein the vacuum chamber is at a pressure ranging from 1.0⁻⁴-1.0⁻² mbar during the step of introducing the process gas containing the nitrogen or argon into the vacuum chamber.

25. The method of claim 22, wherein the step of applying the top layer includes providing an arc in a vacuum chamber during the PVD process.

26. The method of claim 22, wherein the top layer contains nitrogen, and including the step of increasing the amount of nitrogen provided during the step of applying the top layer.

27. The method of claim 22, wherein, the top layer, in an as-formed condition prior to any smoothing process, has a roughness (Rz) of greater than 2 μm, a roughness (Rk) of greater than 0.6 μm, and a roughness (Rpk) of greater than 0.2 μm.
